(19) United States
(12) Patent Application Publication
(10) Pub. No.: US 2025/0201633 A1
(43) Pub. Date: Jun. 19, 2025

(54) THERMAL CHARACTERIZATION METHOD AND MANUFACTURING OF SEMICONDUCTOR PACKAGE

(71) Applicant: Taiwan Semiconductor Manufacturing Company, Ltd., Hsinchu (TW)

(72) Inventors: Sam Vaziri, San Jose, CA (US); Isha Datye, Hsinchu (TW); Xinyu BAO, Fremont, CA (US)

(73) Assignee: Taiwan Semiconductor Manufacturing Company, Ltd., Hsinchu (TW)

(21) Appl. No.: 18/403,662

(22) Filed: Jan. 3, 2024

Related U.S. Application Data
(60) Provisional application No. 63/609,353, filed on Dec. 13, 2023.

(51) Int. Cl. H01L 21/66; G01N 23/20; H01L 21/768; H01L 23/00

(52) U.S. Cl. CPC H01L 22/12; G01N 23/20; H01L 21/768; H01L 24/80; G01N 2223/6116; H01L 2224/80895; H01L 2224/80896

(57) ABSTRACT

A thermal characterization method and a method for manufacturing a semiconductor package are provided. The thermal characterization method includes: conducting preliminary experiments before manufacturing of the semiconductor structure, to establish correlations between crystal properties and thermal properties of thin film samples formed of a crystalline material identical with a crystalline material for forming the thermal conductive layer; performing a grazing angle X-ray diffraction (GIXRD) characterization on the thermal conductive layer during manufacturing of the semiconductor structure, and extracting crystal properties of the thermal conducive layer from a resulted diffractogram; and using the correlations established by the preliminary experiments to find thermal properties corresponding to the extracted crystal properties of the thermal conductive layer.

### CROSS-REFERENCE TO RELATED APPLICATION

This application claims the priority benefit of U.S. provisional application Ser. No. 63/609,353, filed on Dec. 13, 2023. The entirety of the above-mentioned patent application is hereby incorporated by reference herein and made a part of this specification.

### BACKGROUND

With enhanced performance requirement for more compact, miniaturized, and high-density semiconductor packages, considerable attention has been given to heat dissipation problem of the semiconductor packages. Efficient removal of heat from semiconductor packages has become a crucial issue to offer promising performance without functional failure. While heat fluxes in semiconductor packages have been significantly increased, thermal design margins are continuing to decline for heat dissipation, which has led to an increase in demand for advanced thermal conductive materials. Several ceramic-based materials can greatly meet these requirements, while offering dielectric isolation to prevent electrical short. However, currently there is lack of an accurate and reliable thermal characterization technique for monitoring and analyzing thermal characteristics of the thermal conductive materials during manufacturing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic side-view illustrating an X-ray diffraction (XRD) apparatus used for investigating crystal structure of a thermal conductive layer during manufacturing of a semiconductor package, according to some embodiments of the present disclosure.

FIG. 2A, FIG. 2B, FIG. 2C and FIG. 2D show results concluded from preliminary experiments.

FIG. 3 is a flow diagram illustrating a process for manufacturing a semiconductor package, according to some embodiments of the present disclosure.

FIG. 4A through FIG. 4D show operations at various stages during the manufacturing process as shown in FIG. 3.

FIG. 5A is a schematic cross-sectional view illustrating a die stacking structure in a semiconductor package, according to some embodiments of the present disclosure.

FIG. 5B is a schematic cross-sectional view illustrating a die stacking structure in a semiconductor package, according to some embodiments of the present disclosure.

FIG. 6 is a schematic cross-sectional view illustrating a semiconductor die, according to some embodiments of the present disclosure.

FIG. 7A is a schematic cross-sectional view illustrating a die stacking structure in a semiconductor package, according to some embodiments of the present disclosure.

FIG. 7B is a schematic cross-sectional view illustrating a die stacking structure in a semiconductor package, according to some embodiments of the present disclosure.

FIG. 8 is a schematic cross-sectional view illustrating a portion of a semiconductor package, according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a solution for characterizing a thermal conductive layer during manufacturing of a semiconductor package.

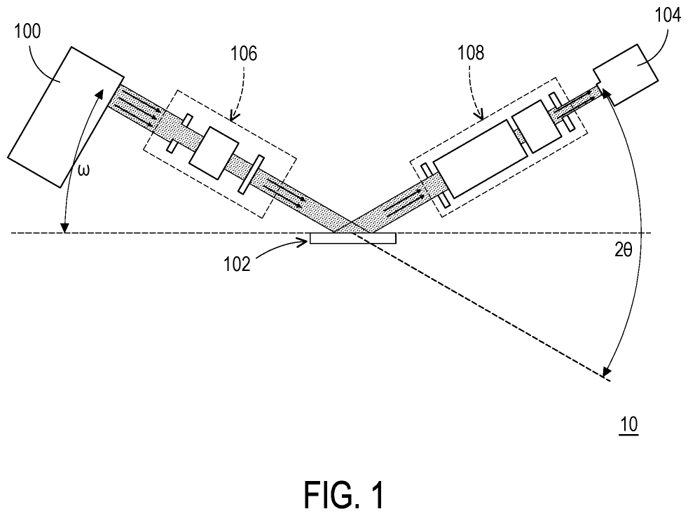

FIG. 1 is a schematic side-view illustrating an X-ray diffraction (XRD) apparatus 10 used for investigating crystal structure of a thermal conductive layer during manufacturing of a semiconductor package, according to some embodiments of the present disclosure.

The XRD apparatus 10 includes an X-ray emission module 100 configured to emit X-ray beams to a workpiece 102. The incident X-ray beams may interact with (e.g., be scattered by) crystal structure in the workpiece 102, and a detector 104 is positioned to collect diffracted X-ray beams. As a result of destructive diffraction and constructive diffraction, some of the diffracted X-ray beams cancel each other out, while others of the diffracted X-ray beams are added to create a new beam with higher amplitude. In this way, a diffraction pattern as a fingerprint of the crystal structure in the workpiece 102 can be sensed by the detector 104, and the crystal structure can be analyzed by extracting information from the diffraction pattern. According to some embodiments, the X-ray beams may pass through a set of incident optics 106 before striking the workpiece 102. Similarly, in some embodiments, the diffracted X-ray beams may pass through receiving optics 108 before being collected by the detector 104.

The workpiece 102 may be an intermediate structure during manufacturing of a semiconductor package, and a thermal conductive layer is exposed at an X-ray receiving surface of the workpiece 102. Rather than being a bulk structure, the thermal conductive layer is in a form of thin film. As an example (but not limited to), a thickness of the thermal conductive layer may be no greater than 500 nm. In order to target such shallow region of the workpiece 102, penetration depth by which the X-ray beams enter the workpiece 102 should be limited. Therefore, an incident beam angle ω defined between paths of the incident X-ray beams and the X-ray receiving surface of the workpiece 102 is fixed at a very small angle, such as 0.1° to 5°. By keeping a low incident beam angle ω, the XRD is also referred to as grazing angle XRD (GIXRD).

While the X-ray emission module 100 may be fixed, the detector 104 may move along a circle around the workpiece 102, and position of the detector 104 may be represented by an angle 2θ, which is defined between the incident X-ray beams and the diffracted X-ray beams. Also, the detector 104 records counts of X-ray at each value of the angle 2θ. In this way, a plot of X-ray intensity on Y-axis versus the angle 2θ on X-axis can be obtained. This plot, which may also be referred to as a diffractogram, reveals information about the crystal structure of the thermal conductive layer exposed at the X-ray receiving surface of the workpiece 102. As will be described in greater details, thermal properties of the thermal conductive layer can be predicted by extracting and analyzing the crystal information from the diffractogram.

The thermal conductive layer in the workpiece 102 is formed of a thermal conductive material. As compared to other candidates, certain ceramic based thermal conductive materials can provide great thermal conductivity, while offering dielectric isolation to prevent electrical short. AlN is one of these ceramic based thermal conductive materials that further shows great compatibility to back-end-of-line (BEOL) process, and the thermal characterization method will be described according to an example of which the target thermal conductive layer is formed of AlN.

Among other crystalline planes, (002) and (103) crystalline planes exist in AlN crystal structure (i.e., Wurtzite structure). In single crystalline AlN, the (002) plane is normal to direction, and the GIXRD cannot detect the (002) plane. That is, a peak corresponding to the (002) plane would be absent in the diffractogram. However, crystal grains in polycrystalline AlN may have a preferential orientation, and may be particularly longer in one direction. This results that a normal direction of the (002) plane in polycrystalline AlN may be tilted from the [001] direction, and a peak corresponding to the (002) plane may be shown at the angle 2θ of about 66° in the diffractogram. On the other hand, a normal direction of the (103) crystalline plane is tilted from the [001] direction under various conditions. A peak corresponding to the (103) crystalline plane may be shown at the angle 2θ of about 36° in the diffractogram. Hereinafter, the peak corresponding to the (002) crystalline plane will be simply referred to as a (002) peak, and the peak corresponding to the (103) crystalline plane will be simply referred to as a (103) peak.

Based on results of a series of preliminary experiments, anisotropy of thermal conductivity of the AlN thermal conductive layer is found to be highly dependent on an intensity ratio of the (103) peak with respect to the (002) peak. The anisotropy of thermal conductivity is defined as a ratio of cross-plane (vertical) thermal conductivity over in-plane (lateral) thermal conductivity, and is simply referred to as thermal anisotropy hereinafter. When the intensity ratio of the (103) peak with respect to the (002) peak is high, the (002) peak is rather weak, and the normal direction of the (002) crystalline plane is less tilted from the [001] direction. It indicates that crystal grains in the AlN thermal conductive layer are more aligned with the [001] direction, which may result in more efficient thermal conduction along a vertical direction, and therefore the AlN thermal conductive layer is resulted with a higher thermal anisotropy. On the other hand, when the intensity ratio of the (103) peak with respect to the (002) peak is low, the (002) peak is rather strong, and the normal direction of the (002) crystalline plane is more tilted from the direction. In this case, the crystal grains in the AlN thermal conductive layer are less aligned with the [001] direction, which may result in less efficient thermal conduction along the vertical direction, and therefore the AlN thermal conductive layer is resulted with a lower thermal anisotropy.

Instead of being roughly estimated, the thermal anisotropy of the AlN thermal conductive layer can be accurately predicted. Specifically, according to the results of the preliminary experiments, the cross-plane thermal conductivity of the AlN thermal conductive layer is in positive correlation with the intensity ratio of the (103) peak with respect to the (002) peak when this intensity ratio is greater than 1, while being a function of grain size of the AlN crystal grains along the (002) crystalline plane when this intensity ratio is less than 1. In addition, the thermal anisotropy of the AlN thermal conductive layer varies according to the cross-plane thermal conductivity of the AlN thermal conductive layer. That is, the cross-plane thermal conductivity of the AlN thermal conductive layer can be found as the intensity ratio of the (103) peak with respect to the (002) peak (and the grain size of the AlN crystal grains along the (002) crystalline plane) is/are determined, and then the thermal anisotropy of the AlN thermal conductive layer can be accurately predicted by the determined cross-plane thermal conductivity.

During the preliminary experiments, multiple AlN thin film samples are prepared. The samples respectively include an AlN layer similar to that in the workpiece 102 (which may be an intermediate structure of a semiconductor package, as described above), but the samples may not have an integrated circuit lying below each AlN layer, and are formed by using different process parameters so as to be different from one another in terms of alignment of crystal grains. By applying the described GIXRD characterization to these samples, a diffractogram for each sample can be obtained. Accordingly, the intensity ratio of the (103) peak with respect to the (002) peak for each sample can be extracted from the corresponding diffractogram. In addition, for each sample, grain size of the AlN crystal grains along the (002) crystalline plane can be calculated by using full width at maximum height (FWMH) of the (002) peak. Further, cross-plane thermal conductivity for each sample can be directly measured. As an example (but not limited to), an electrothermal method may be used for measuring the cross-plane thermal conductivity for each sample. By having the extracted crystal information and the measured cross-plane thermal conductivity, correlations in between can be found. To be more specific, for those samples with the intensity ratio (the ratio of the intensity of the (103) peak with respect to the intensity of the (002) peak) greater than 1, the described positive correlation between the intensity ratio and the cross-plane thermal conductivity can be determined. Also, for those samples with the intensity ratio (of the (103) peak with respect to the (002) peak) less than 1, the function describing how the grain size relates to the cross-plane thermal conductivity can be obtained.

Moreover, the preliminary experiments further include directly measuring in-plane thermal conductivity for each sample. Therefore, how the thermal anisotropy (which is defined as a ratio of cross-plane thermal conductivity over in-plane thermal conductivity) varies according to the cross-plane thermal conductivity can be identified. As an example (but not limited to), an electrothermal method or a thermal reflectance method may be used for measuring the in-plane thermal conductivity for each sample.

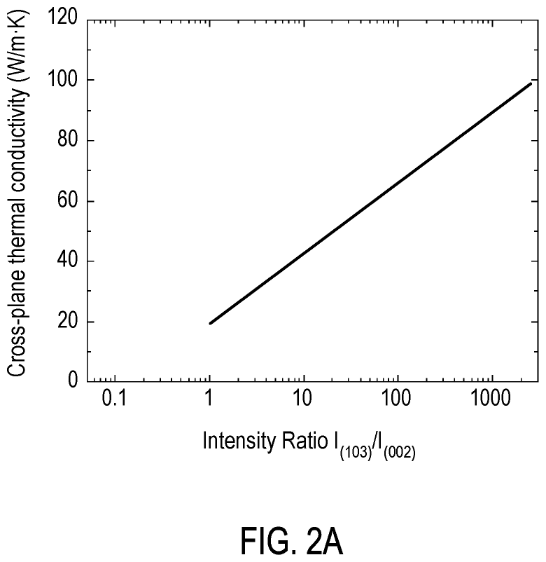

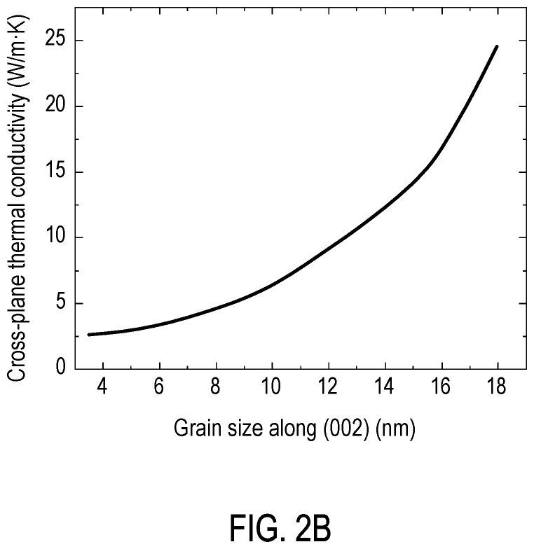

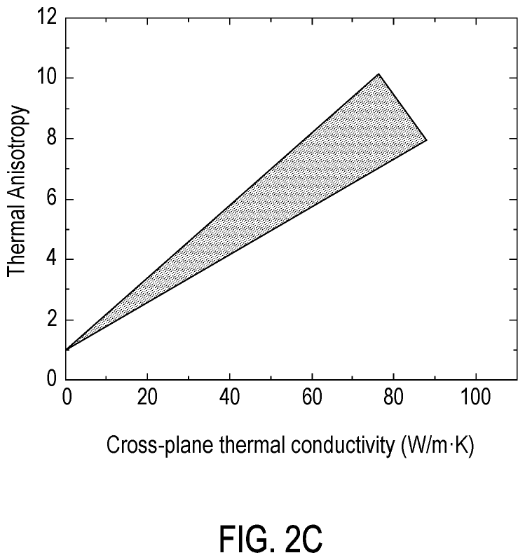

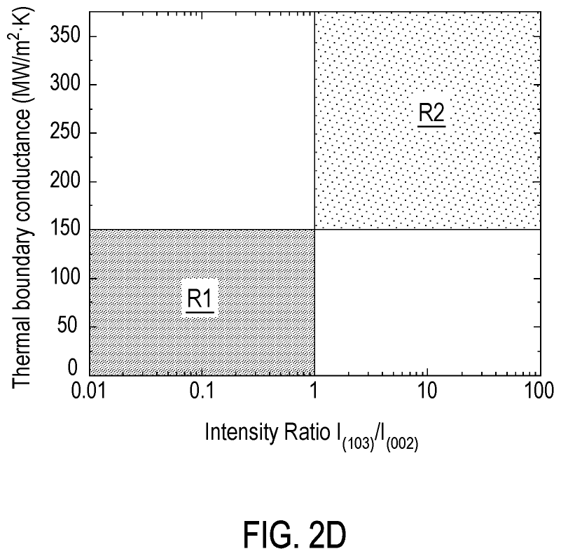

FIG. 2A is a plot showing the positive correlation between the intensity ratio (of the (103) peak with respect to the (002) peak) and the cross-plane thermal conductivity for the samples with the intensity ratio greater than 1. FIG. 2B is a plot showing the function describing how the grain sizes along the (002) crystalline plane relates to the cross-plane thermal conductivity for the samples having the intensity ratio (of the (103) peak with respect to the (002) peak) less than 1. FIG. 2C is a plot showing how the thermal anisotropy varies according to the cross-plane thermal conductivity for all of the samples.

As shown in FIG. 2A, for the samples with the intensity ratio (of the (103) peak with respect to the (002) peak) greater than 1, the measured cross-plane thermal conductivity may be in a positive linear relationship with logarithm of the intensity ratio. As shown in FIG. 2B, for the samples with the intensity ratio (of the (103) peak with respect to the (002) peak) less than 1, the measured cross-plane thermal conductivity is a function (e.g., an exponential function) of the grain size along the (002) crystalline plane. Further, as shown in FIG. 2C, the thermal anisotropy as a ratio of the measured cross-plane thermal conductivity over the measured in-plane thermal conductivity varies according to the cross-plane thermal conductivity. To be more specific, each value of the cross-plane thermal conductivity may correspond to a specific range of thermal anisotropy, and the thermal anisotropy corresponding to a higher value of the cross-plane thermal conductivity may vary more greatly than the thermal anisotropy corresponding to a lower value of the cross-plane thermal conductivity. On average, the thermal anisotropy is in positive relationship with the cross-plane thermal conductivity.

These results of the preliminary experiments can be used for accurately predicting the cross-plane thermal conductivity and the thermal anisotropy of the AlN thermal conductive layer in the workpiece 102 (which may be an intermediate structure of a semiconductor package, as described), without directly measuring them. Specifically, based on the results shown in FIG. 2A and FIG. 2B, the cross-plane thermal conductivity of the AlN thermal conductive layer in the workpiece 102 can be predicted by using the intensity ratio of the (103) peak with respect to the (002) peak (and also the grain size) obtained by performing the described GIXRD characterization. Once the cross-plane thermal conductivity is identified, the thermal anisotropy of the AlN thermal conductive layer in the workpiece 102 can be obtained by using the result shown in FIG. 2C.

According to some embodiments, the preliminary experiments further include measuring a thermal boundary conductance across an interface between the AlN layer and an underlying substrate for each sample. Result shows that the thermal boundary conductance is also related to the intensity ratio of the (103) peak with respect to the (002) peak for all of the samples.

FIG. 2D is a plot showing a relationship between the thermal boundary conductance and the intensity ratio (of the (103) peak with respect to the (002) peak) for all of the samples.

As shown in FIG. 2D, for the samples with the intensity ratio (of the (103) peak with respect to the (002) peak) less than 1, the thermal boundary conductance may be within a lower range R1, such as from about 0 MW/m²·K to about 150 MW/m²·K. On the other hand, for the samples with the intensity ratio (of the (103) peak with respect to the (002) peak) greater than 1, the thermal boundary conductance may be within a higher range R2, such as from about 150 MW/m²·K to over 350 MW/m²·K.

Accordingly, a thermal boundary conductance across an interface between the AlN thermal conductive layer and an underlying layer in the workpiece 102 can be predicted by using the intensity ratio (of the (103) peak with respect to the (002) peak) extracted from the diffractogram of the workpiece 102 and the preliminary work shown in FIG. 2D, without directly measuring the thermal boundary conductance of the workpiece 102. In order to provide similar boundary condition, a material of the substrate supporting the AlN layer in each sample may be identical with a material of a layer lying under the AlN thermal conductive layer in the workpiece 102. In an example that the AlN thermal conductive layer in the workpiece 102 lies on a silicon oxide layer, the AlN layer in each sample may be formed on a silicon oxide substrate.

As described, according to the preliminary experiments, correlations between crystal information and thermal properties of the AlN samples can be determined. Once having these correlations, thermal properties of an AlN thermal conductive layer in an under-manufacturing workpiece can be predicted by performing the GIXRD characterization on the workpiece and extracting crystal information from the resulted diffractogram, without directly measuring the thermal properties of the workpiece. Since the GIXRD characterization is non-destructive, the workpiece can still be subjected to rest process steps after completing the GIXRD characterization. Therefore, this provides an in-line solution for monitoring thermal properties of a thermal conductive layer during manufacturing.

According to other embodiments, the preliminary experiments further include performing compositional analysis on the AlN samples. In this way, not only the described correlations between the thermal properties and the crystal information of AlN layers can be established, but also correlation between the thermal properties and elemental compositions of the AlN layers. For instance (but not limited to), according to results of the preliminary experiments, AlN layers with oxygen content below 2% and/or aluminum to nitrogen ratio greater than 0.9 and less than 1 may have thermal anisotropy greater than 4 and thermal boundary conductance over 200 MW/m²/K. In these embodiments, thermal properties of an AlN thermal conductive layer in an under-manufacturing workpiece can be further confirmed by performing a compositional analysis.

It should be appreciated that the disclosed thermal characterization method should not be limited to only targeting the AlN thermal conductive layer. Similar correlations between thermal properties and crystal information (and correlations between the thermal properties and elemental compositions) can be found for other crystalline thermal conductive materials by the same approach, thus thermal properties of a thermal conductive layer formed by any of these crystalline thermal conductive materials can be predicted by applying the GIXRD characterization and extracting the crystal information from the resulted diffractogram, and may be confirmed by further performing a compositional analysis. As examples (but not limited to), the available crystalline thermal conductive materials may include hexagonal boron nitride (h-BN), cubic boron nitride (c-BN), diamond, boron phosphide (BP), beryllium oxide (BeO) and aluminum oxide (Al₂O₃).

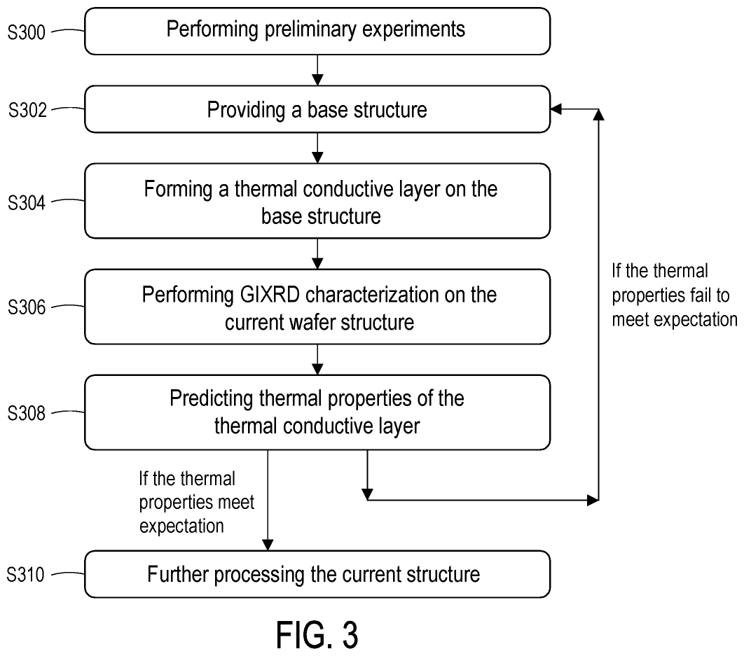

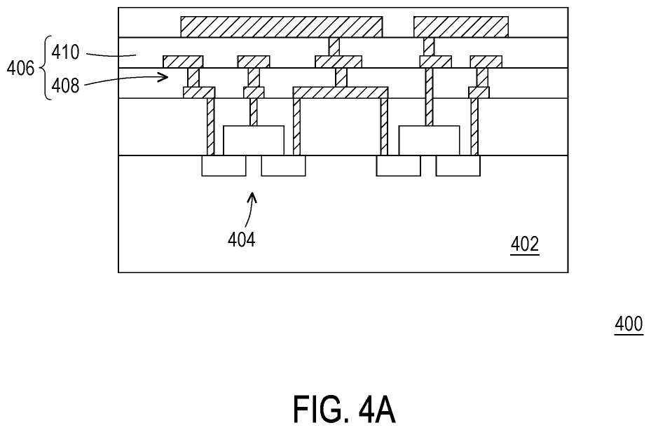

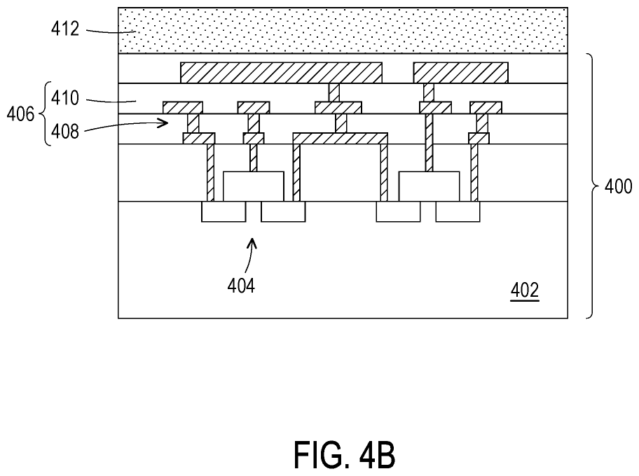

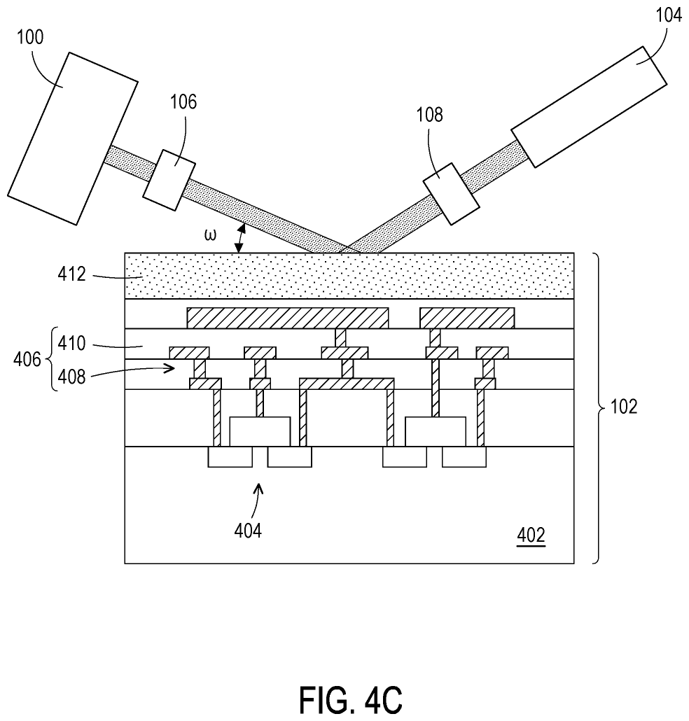

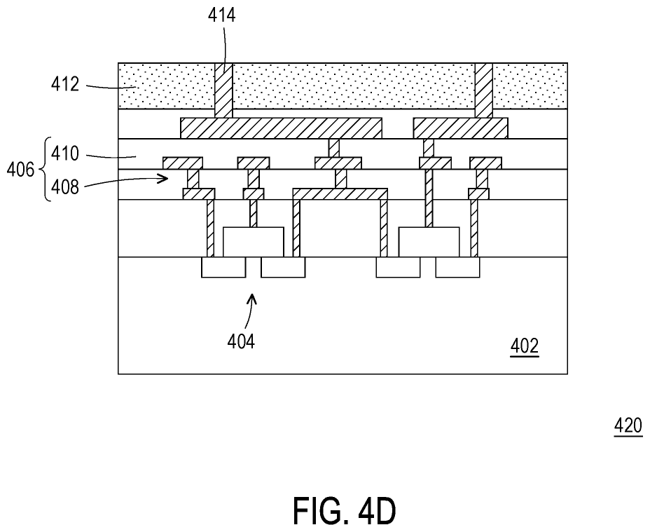

FIG. 3 is a flow diagram illustrating a process for manufacturing a semiconductor package, according to some embodiments of the present disclosure. FIG. 4A through FIG. 4D show operations at various stages during the manufacturing process as shown in FIG. 3.

The manufacturing process includes an in-line thermal characterization targeting a thermal conductive layer in the semiconductor package. As shown in FIG. 3, prior to wafer processing, a step S300 is performed to conduct the preliminary experiments described above, to identify the correlations between thermal properties and crystal information (as well as the correlation between the thermal properties and elemental compositions) of thin film samples formed of a thermal conductive material used later for forming the thermal conductive layer in the semiconductor package.

Referring to FIG. 3 and FIG. 4A, the wafer processing may begin from a step S302, at which a base structure 400 for forming a thermal conductive layer is provided. According to some embodiments, the base structure 400 includes a semiconductor substrate 402 (e.g., a silicon wafer), active devices 404 formed on the semiconductor substrate 402 and metallization layers 406 stacked over the active devices 404. The active devices 404 may include metal-oxide-semiconductor field effect transistors (MOSFETs), which may be implemented by planar type field effect transistors (FETs), fin-type FETs (FinFETs) or gate-all-around FETs (GAA-FETs). Conductive features 408 (e.g., conductive lines and conductive vias) of the metallization layers 406 are configured to interconnect and out-rout the active devices 404, and are embedded in a stack of dielectric layers 410. As an example, the dielectric layers 410 are formed of a silicon-based dielectric material, such as silicon dioxide, borophosphosilicate glass (BPSG), spin-on glass (SOG), tetra-ethyl-ortho-silicate (TEOS), undoped silicate glass (USG), fluorinated silicate glass (FSG), a low-k dielectric material or the like. Those skilled in the art may select a suitable front-end-of-line (FEOL) process for forming the active devices 404. In addition, a back-end-of-line (BEOL) process, which may include repetition of damascene process, is performed for forming the metallization layers 406.

Referring to FIG. 3 and FIG. 4B, at a step S304, the thermal conductive layer (described as a thermal conductive layer 412 hereinafter) is formed on the base structure 400. Accordingly, a topmost one of the dielectric layers 410 is covered by the thermal conductive layer 412. As compared to the dielectric layers 410, the thermal conductive layer 412 has a greater thermal conductivity, for efficiently dissipating heat mostly generated from the underlying active devices 404. To be more specific, the thermal conductive layer 412 may be expected to have a promising cross-plane thermal conductivity (therefore a rather high thermal anisotropy), for efficiently conducting heat from an underlying heat source to a top side of the thermal conductive layer 412. As described, the thermal conductive layer 412 may be formed of a ceramic based thermal conductive material, such as AlN, hexagonal boron nitride (h-BN), cubic boron nitride (c-BN), diamond, boron phosphide (BP), beryllium oxide (BeO) or aluminum oxide (Al₂O₃). According to some embodiments, a deposition process may be involved for forming the thermal conductive layer 412. For instances, the deposition process may include a chemical vapor deposition (CVD) process, a physical vapor deposition (PVD) process, an atomic layer deposition (ALD) process or the like. Optionally, an annealing process may be performed after the deposition process, to remove defects from the thermal conductive layer 412 and/or to enhance crystal growth of the thermal conductive layer 412.

Referring to FIG. 3 and FIG. 4C, at a step S306, the current wafer structure is provided as the workpiece 102 for the GIXRD characterization described with reference to FIG. 1. To be more specific, the wafer structure shown in FIG. 4B is subjected to the GIXRD characterization without being cut into small pieces or covered by an additional material layer. As destructive sampling is not required and the GIXRD characterization is non-destructive as well, the current wafer structure can be further processed after the GIXRD characterization.

As shown in FIG. 4C, during the GIXRD characterization, the thermal conductive layer 412 is exposed at the X-ray receiving surface of the workpiece 102. Since the incident beam angle ω is kept very small, X-ray penetration depth from the X-ray receiving surface is limited. Specifically, the X-ray penetration depth from the X-ray receiving surface is controlled to be less than a thickness of the thermal conductive layer 412, such that the incident X-ray beams can only interact with crystal structure in the thermal conductive layer 412. Accordingly, the resulted diffractogram can authentically reflect the crystal structure in the thermal conductive layer 412.

Subsequently, at a step S308, the crystal information obtained in the step S306 can be used for predicting thermal properties of the thermal conductive layer 412, based on the results concluded from the preliminary experiments. That is, the thermal properties of the thermal conductive layer 412 are not directly measured, but are predicted by translating the result of the GIXRD characterization according to the correlations found in the preliminary experiments.

If the predicted thermal properties of the thermal conductive layer 412 fail to meet predetermined specification, then a cycle of the steps S302, S304, S306, S308 may be repeated again, and process parameters for forming the thermal conductive layer 412 at the step S304 are adjusted. The repetition may continue, until the thermal conductive layer 412 have expected thermal properties.

When the predicted thermal properties of the thermal conductive layer 412 meet the predetermined specification, then the manufacturing process may proceed to a step S310, at which the current wafer structure is further processed. As an example shown in FIG. 4D, additional conductive features 414 (e.g., conductive vias) may be further formed in the qualified thermal conductive layer 412, and formation of the conductive features 414 may involve a damascene process. The conductive features 408 in the metallization layers 406 are electrically connected to the conductive features 414 in the thermal conductive layer 412, and can be routed to a top side of the thermal conductive layer 412. Without being limited to, the metallized thermal conductive layer 412 may be considered as an additional metallization layer, which is similar to each of the underlying metallization layers 406, except for having improved thermal conductivity.

In certain embodiments, fabrication of a device wafer has been completed at the current stage. Subsequently, a singulation process may be performed, and a resulted semiconductor die 420 may be resulted. Although not shown, the semiconductor die 420 may be further packaged for forming a semiconductor package.

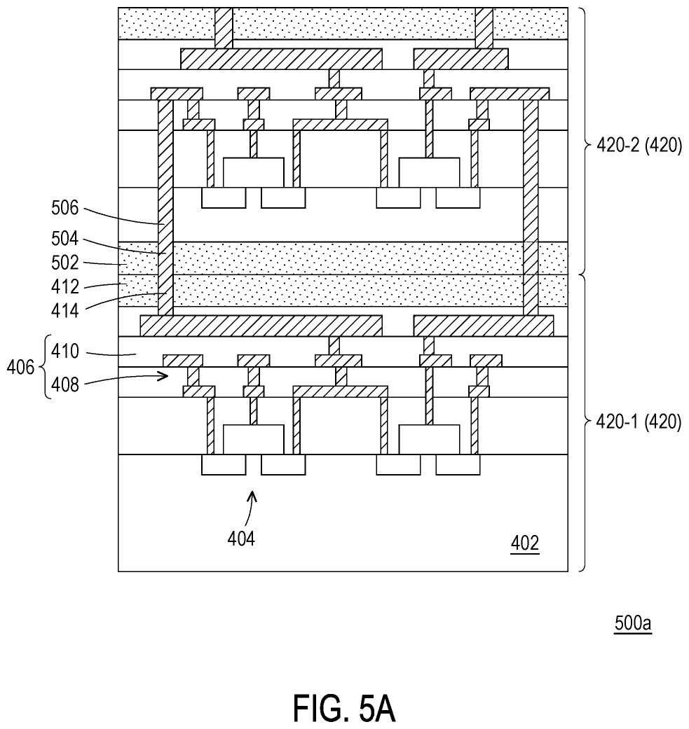

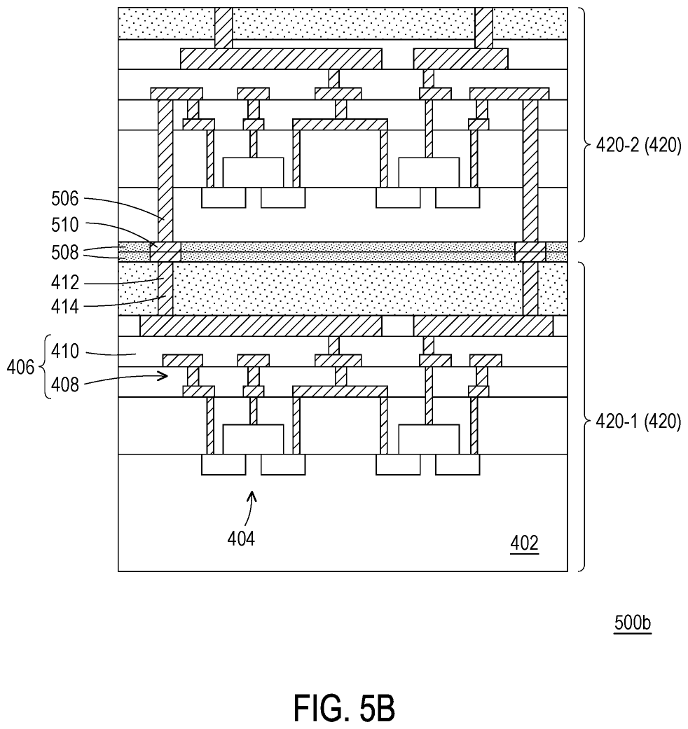

FIG. 5A is a schematic cross-sectional view illustrating a die stacking structure 500a in a semiconductor package, according to some embodiments of the present disclosure.

Formation of the die stacking structure 500a may involve bonding two of the semiconductor dies 420 shown in FIG. 4D. In some embodiments, the semiconductor dies 420 are bonded with each other via a face-to-back manner. In these embodiments, the thermal conductive layer 412 on a first one of the semiconductor dies 420 (referred to as a first semiconductor die 420-1) is attached to a back side of the semiconductor substrate 402 in the other semiconductor die 420 (referred to as a second semiconductor die 420-2). Specifically, an additional thermal conductive layer 502 may be further formed along the back side of the semiconductor substrate 402 in the second semiconductor die 420-2, and the thermal conductive layer 412 in the first semiconductor die 420-1 may be bonded to the thermal conductive layer 502 in the second semiconductor die 420-2, so as to be in contact with the semiconductor substrate 402 of the second semiconductor die 420-2 via the additional thermal conductive layer 502. In addition, the conductive features 414 formed in the thermal conductive layer 412 of the first semiconductor die 420-1 may be in contact with conductive features 504 formed in the additional thermal conductive layer 502 of the second semiconductor die 420-2. Further, the conductive features 504 may be connected to a front side of the second semiconductor die 420-2 along through substrate vias 506 formed through the semiconductor substrate 402 of the second semiconductor die 420-2.

As similar to the thermal conductive layer 412 at a front side of the first semiconductor die 420-1, the additional thermal conductive layer 502 at a back side of the second semiconductor die 420-2 may be formed of a ceramic based thermal conductive material, such as AlN, hexagonal boron nitride (h-BN), cubic boron nitride (c-BN), diamond, boron phosphide (BP), beryllium oxide (BeO) or aluminum oxide (Al₂O₃). Optionally, thermal properties of the additional thermal conductive layer 502 in the second semiconductor die 420-2 can be monitored by the described thermal characterization method right after deposition.

Moreover, the die stacking structure 500a may be further processed to form a semiconductor package. At least, the die stacking structure 500a may be encapsulated by a molding compound, and integrated circuits in the semiconductor dies 420 may be routed to package inputs/outputs (I/Os) exposed at a side (e.g., a bottom side) of the semiconductor package.

FIG. 5B is a schematic cross-sectional view illustrating a die stacking structure 500b in a semiconductor package, according to some embodiments of the present disclosure.

The die stacking structure 500b is similar to the die stacking structure 500a described with reference to FIG. 5A, except for a few differences. Specifically, the first semiconductor die 420-1 and the second semiconductor die 420-2 in the die stacking structures 500b may be bonded via a pair of bonding layers 508. A first bonding layer 508 is formed on the thermal conductive layer 412 of the first semiconductor die 420-1, and first bonding pads 510 formed in the first bonding layer 508 are in contact with the conductive features 414 in the thermal conductive layer 412 of the first semiconductor die 420-1. On the other hand, a second bonding layer 508 may be formed along the back side of the semiconductor substrate 402 in the second semiconductor die 420-2, and second bonding pads 510 are formed in the second bonding layer 508. The first bonding layer 508 along a front side of the first semiconductor die 420-1 is bonded to the second bonding layer 508 along a back side of the second semiconductor die 420-2, and the first bonding pads 510 in the first bonding layer 508 are bonded with the second bonding pads 510 in the second bonding layer 508. Further, the second bonding pads 510 in the second bonding layer 508 may be routed to a front side of the second semiconductor die 420-2 along the through substrate vias 506 extending through the semiconductor substrate 402 of the second semiconductor die 420-2.

According to some embodiments, the bonding layers 508 are formed of a dielectric material different from the thermal conductive material for forming the thermal conductive layers 412. For instance, while the thermal conductive layers 412 are formed of AlN, the bonding layers 508 may be formed of silicon oxide.

As similar to the die stacking structure 500a described with reference to FIG. 5A, the die stacking structure 500b may be further processed to form a semiconductor package. At least, the die stacking structure 500b may be encapsulated by a molding compound, and integrated circuits in the semiconductor dies 420 of the die stacking structure 500b may be routed to package I/Os exposed at a side (e.g., a bottom side) of the semiconductor package.

In further embodiments, more wafer processing steps may be performed on the wafer structure shown in FIG. 4D before singulation and packaging.

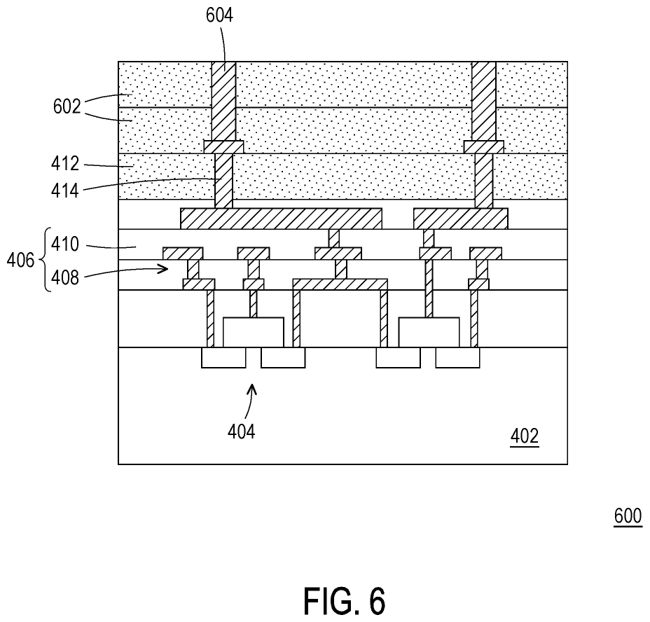

FIG. 6 is a schematic cross-sectional view illustrating a semiconductor die 600, according to some embodiments of the present disclosure.

The semiconductor die 600 may be obtained by further processing the wafer structure shown in FIG. 4D and singulating the resulted device wafer. Specifically, additional thermal conductive layers 602 may be formed on the thermal conductive layer 412. As similar to the thermal conductive layer 412, the additional thermal conductive layers 602 may be formed of a ceramic based thermal conductive material, such as AlN, hexagonal boron nitride (h-BN), cubic boron nitride (c-BN), diamond, boron phosphide (BP), beryllium oxide (BeO) or aluminum oxide (Al₂O₃). After formation of each thermal conductive layer 602, the resulted structure can be optionally subjected to the steps S306, S308 for determining thermal properties of the as-deposited additional thermal conductive layer 602. Also, additional conductive features 604 (e.g., conductive vias and conductive pads/lines) may be further formed in the additional thermal conductive layers 602. Subsequently, a singulation process may be performed on the resulted device wafer, and the semiconductor die 600 may be obtained.

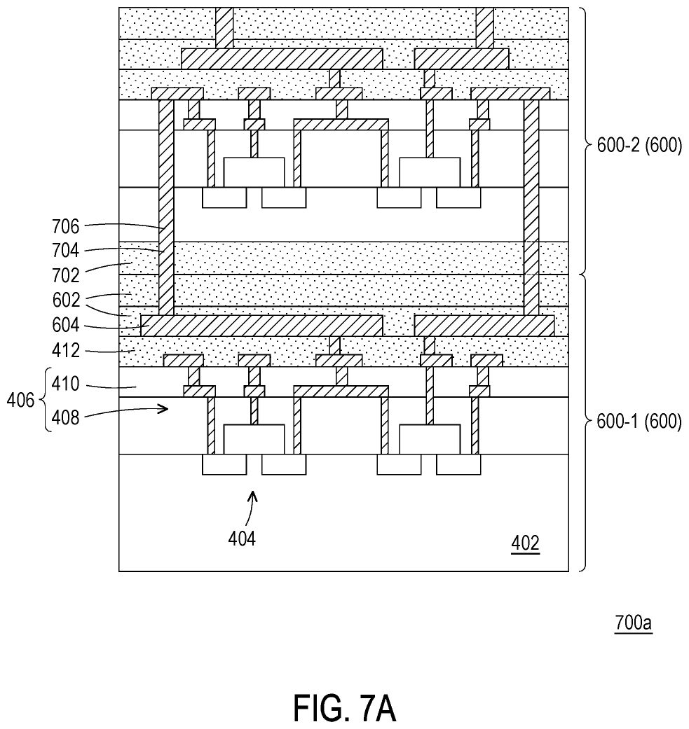

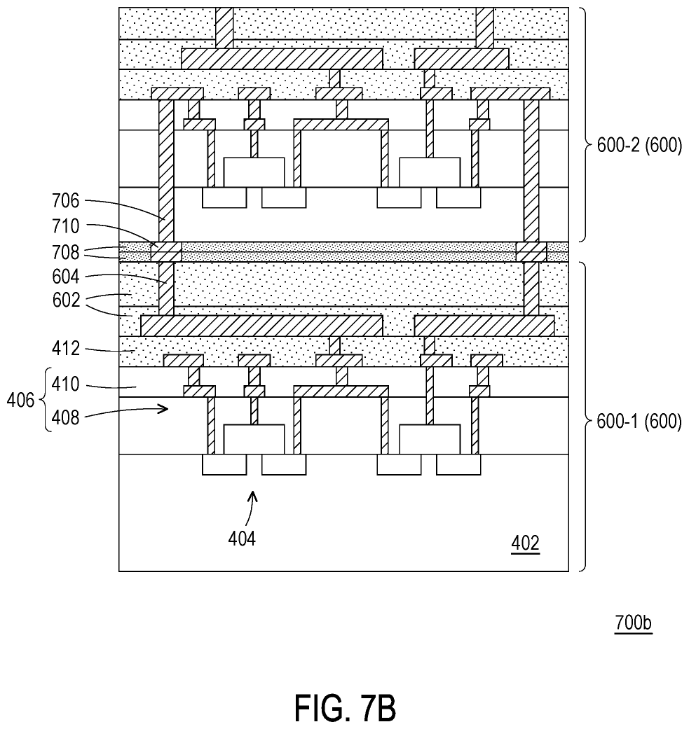

FIG. 7A is a schematic cross-sectional view illustrating a die stacking structure 700a in a semiconductor package, according to some embodiments of the present disclosure.

Referring to FIG. 7A, formation of the die stacking structure 700a may involve bonding two of the semiconductor dies 600 shown in FIG. 6. According to a face-to-back bonding manner, the outermost thermal conductive layer 602 in one of the semiconductor dies 600 (referred to as a first semiconductor die 600-1) is bonded to an additional thermal conductive layer 702 formed along a back side of the semiconductor substrate 402 in the other semiconductor die 600 (referred to as a second semiconductor die 600-2). In addition, the conductive features 604 formed in the outermost thermal conductive layer 602 of the first semiconductor die 600-1 are bonded with conductive features 704 formed in the thermal conductive layer 702 of the second semiconductor die 600-2. Further, the conductive features 704 may be routed to a front side of the second semiconductor die 600-2 along through substrate vias 706 formed through the semiconductor substrate 402 of the second semiconductor die 600-2.

FIG. 7B is a schematic cross-sectional view illustrating a die stacking structure 700b in a semiconductor package, according to some embodiments of the present disclosure.

The die stacking structure 700b is similar to the die stacking structure 700a described with reference to FIG. 7A, except that the semiconductor dies 600 in the die stacking structure 700b are bonded with each other via a pair of bonding layers 708 lying in between the semiconductor dies 600. Specifically, one of the bonding layers 708 is formed on the outermost thermal conductive layer 602 in the first semiconductor die 600-1, while the other bonding layer 708 is formed along a back side of the semiconductor substrate 402 of the second semiconductor die 600-2. These bonding layers 708 are bonded with each other. In addition, bonding pads 710 formed in one of the bonding layers 708 are bonded with bonding pads 710 formed in the other bonding layer 708. According to some embodiments, the bonding pads 710 formed in the bonding layer 708 extending along the back side of the semiconductor substrate 402 of the second semiconductor die 600-2 are further routed by the through substrate vias 706.

According to some embodiments, the bonding layers 708 are formed of a dielectric material different from the thermal conductive material for forming the thermal conductive layers 412, 602. For instance, while the thermal conductive layers 412, 602 are formed of AlN, the bonding layers 708 may be formed of silicon oxide.

Although not explicitly illustrated, either the die stacking structure 700a shown in FIG. 7A or the die stacking structure 700b shown in FIG. 7B may be further processed to form a semiconductor package. At least, the die stacking structures 700a, 700b may be respectively encapsulated by a molding compound, and integrated circuits in the semiconductor dies 600 of the die stacking structures 700a, 700b may be routed to package I/Os configured to engage with external package components.

In the afore-described embodiments, the thermal conductive layer 412 is functioned as a metallization layer and/or a bonding layer for engaging with another semiconductor die. In other embodiments, the thermal conductive layer 412 is attached to a heat dissipation module.

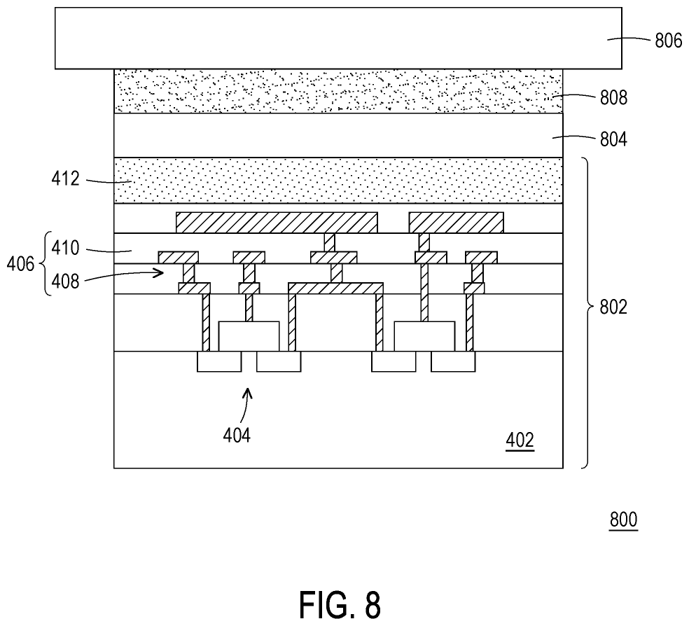

FIG. 8 is a schematic cross-sectional view illustrating a portion of a semiconductor package 800, according to some embodiments of the present disclosure.

The semiconductor package 800 may include a semiconductor die 802 singulated from the wafer structure shown in FIG. 4C. It should be appreciated that the singulation is performed after the thermal conductive layer 412 therein is qualified as having promising thermal properties. The semiconductor die 802 (in wafer form or chip form) may be attached with a carrier 804, which may be a supporting substrate or a heat sink. In addition, the carrier 804 may be attached to a heat dissipation lid 806 by the other side. According to some embodiments, the carrier 804 is attached to the heat dissipation lid 806 via a thermal interfacial layer 808. As the thermal conductive layer 412 is ensured to have great cross-plane thermal conductivities and/or great thermal anisotropy, a thermal resistance at an interface between the semiconductor die 802 and the overlying heat dissipation module can be effectively reduced.

As above, an in-line thermal characterization method is provided. The thermal characterization method is used for instantly monitoring thermal properties of a thermal conductive layer in a semiconductor structure during manufacturing of the semiconductor structure, and for tuning process parameters for forming the thermal conductive layer. Specifically, preliminary experiments are performed before manufacturing of the semiconductor structure, to establish correlations between crystal information and the thermal properties of thin film samples made of the same material as the thermal conductive layer. During manufacturing of the semiconductor structure, a GIXRD analysis is performed on an intermediate structure with the thermal conductive layer exposed at its surface, for determining crystal information of the thermal conductive layer. Based on the correlations concluded from the preliminary experiments, the thermal properties of the as-deposited thermal conductive layer can be accurately predicted by using the determined crystal information. Since the GIXRD analysis is non-destructive and a destructive sampling is not required for the GIXRD analysis, the tested intermediate structure can be further processed for completing fabrication of the semiconductor structure, if the thermal conductive layer therein is ensured to have expected thermal properties. As the semiconductor structure has the qualified thermal conductive layer, efficient heat dissipation of the semiconductor structure may be achieved. On the other hand, if the identified thermal properties of the thermal conductive layer fall below expectation, process parameters for forming the thermal conductive layer may be adjusted.

Even though the semiconductor structure is illustrated as a wafer structure and the thermal conductive layer is described as being formed along a front side or a back side of the wafer structure, it can be appreciated the semiconductor structure may otherwise be a package structure with a semiconductor die and a surrounding encapsulant, and the thermal conductive layer may cover both of the encapsulant and the semiconductor die. The disclosed thermal characterization can be applied for various semiconductor structures each with one or more crystalline thermal conductive layers formed therein.

In an aspect of the present disclosure, a thermal characterization method is provided. The thermal characterization method is used for investigating a thermal conductive layer in a semiconductor structure, and comprises: conducting preliminary experiments before manufacturing of the semiconductor structure, to establish correlations between crystal properties and thermal properties of thin film samples formed of a crystalline material identical with a crystalline material for forming the thermal conductive layer; performing a grazing angle X-ray diffraction (GIXRD) characterization on the thermal conductive layer during manufacturing of the semiconductor structure, and extracting crystal properties of the thermal conducive layer from a resulted diffractogram; and using the correlations established by the preliminary experiments to find thermal properties corresponding to the extracted crystal properties of the thermal conductive layer.

In another aspect of the present disclosure, a method for manufacturing a semiconductor package with a thermal conductive layer is provided. The method comprises: conducting preliminary experiments, to establish correlations between crystal properties and thermal properties of thin film samples formed of a crystalline material identical with a crystalline material for forming the thermal conductive layer; depositing the thermal conductive layer over a substrate; subjecting an intermediate structure with the thermal conductive layer exposed at its surface to a grazing angle X-ray diffraction (GIXRD) characterization, and extracting crystal properties of the thermal conducive layer from a resulted diffractogram; using the correlations established by the preliminary experiments to find thermal properties corresponding to the extracted crystal properties of the thermal conductive layer; and further processing the intermediate structure to complete formation of the semiconductor package.

In yet another aspect of the present disclosure, a method for manufacturing a semiconductor package with a thermal conductive layer is provided. The method comprises: conducting preliminary experiments, to establish correlations between crystal properties and thermal properties of thin film samples formed of a crystalline material identical with a crystalline material for forming the thermal conductive layer; depositing the thermal conductive layer over a substrate; subjecting an intermediate structure with the thermal conductive layer exposed at its surface to a grazing angle X-ray diffraction (GIXRD) characterization, and extracting crystal properties of the thermal conducive layer from a resulted diffractogram; using the correlations established by the preliminary experiments to find thermal properties corresponding to the extracted crystal properties of the thermal conductive layer; determining if at least one of the thermal properties of the thermal conductive layer is greater than a predetermined expectation level; when the at least one of the thermal properties of the thermal conductive layer is greater than the predetermined expectation level, then further processing the intermediate structure to complete formation of the semiconductor package; and if the at least one of the thermal properties of the thermal conductive layer is lower than the predetermined expectation level, then performing a next cycle from depositing another thermal conductive layer on another substrate by using adjusted deposition parameters.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A thermal characterization method, used for investigating a thermal conductive layer in a semiconductor structure, and comprising:
conducting preliminary experiments before manufacturing of the semiconductor structure, to establish correlations between crystal properties and thermal properties of thin film samples formed of a crystalline material identical with a crystalline material for forming the thermal conductive layer;
performing a grazing angle X-ray diffraction (GIXRD) characterization on the thermal conductive layer during manufacturing of the semiconductor structure, and extracting crystal properties of the thermal conducive layer from a resulted diffractogram; and
using the correlations established by the preliminary experiments to find thermal properties corresponding to the extracted crystal properties of the thermal conductive layer.

2. The thermal characterization method according to claim 1, wherein the GIXRD characterization is performed after deposition of the thermal conductive layer and before a next process step for forming the semiconductor structure.

3. The thermal characterization method according to claim 1, wherein the GIXRD characterization is performed without a destructive sampling process.

4. The thermal characterization method according to claim 1, wherein an X-ray penetration depth of the GIXRD characterization is controlled to be less than a thickness of the thermal conductive layer.

5. The thermal characterization method according to claim 1, wherein the thermal properties of each of the thin film samples and the thermal conductive layer comprise a cross-plane thermal conductivity, a thermal anisotropy and a thermal boundary conductance.

6. The thermal characterization method according to claim 1, wherein the crystal properties of each of the thin film samples and the thermal conductive layer comprise an indicator indicating alignment of crystal grains in the crystalline material, and comprise a grain size of the crystal grains.

7. The thermal characterization method according to claim 1, wherein the preliminary experiments comprise performing a preliminary GIXRD for each of the thin film samples to obtain the crystal properties of each of the thin film samples, and comprise measuring the thermal properties of each of the thin film samples.

8. The thermal characterization method according to claim 1, wherein the crystalline material for forming the thin film samples and the thermal conductive layer comprises aluminum nitride, boron nitride, diamond, boron phosphide, beryllium oxide or aluminum oxide.

9. The thermal characterization method according to claim 1, wherein the crystalline material is aluminum nitride, the crystal properties of each of the thin film samples and the thermal conductive layer comprise an intensity ratio of an intensity of a (103) crystalline plane with respect to an intensity of a (002) crystalline plane, and comprise a grain size along the (002) crystalline plane.

10. The thermal characterization method according to claim 9, wherein the preliminary experiments comprise:
performing a preliminary GIXRD for each of the thin film samples for obtaining the intensity ratio and the grain size of each of the thin film samples;
directly measuring a cross-plane thermal conductivity, an in-plane thermal conductivity and a thermal boundary conductance of each of the thin film samples;
identifying a first relationship between a first range of the cross-plane thermal conductivity and a corresponding range of the intensity ratio;
identifying a second relationship between a second range of the cross-plane thermal conductivity and the grain size;
identifying a third relationship between the cross-plane thermal conductivity and a thermal anisotropy as a ratio of the cross-plane thermal conductivity over the in-plane thermal conductivity; and
identifying a fourth relationship between the thermal boundary conductance and the intensity ratio.

11. The thermal characterization method according to claim 10, wherein a cross-plane thermal conductivity of the thermal conductive layer is obtained by using the intensity ratio of the thermal conductive layer and one of the first and second relationships, a thermal anisotropy of the thermal conductive layer is obtained by using the cross-plane thermal conductivity of the thermal conductive layer and the third relationship, and a thermal boundary conductance of the thermal conductive layer is obtained by using the intensity ratio of the thermal conductive layer and the fourth relationship.

12. A method for manufacturing a semiconductor package with a thermal conductive layer, comprising:
conducting preliminary experiments, to establish correlations between crystal properties and thermal properties of thin film samples formed of a crystalline material identical with a crystalline material for forming the thermal conductive layer;
depositing the thermal conductive layer over a substrate;
subjecting an intermediate structure with the thermal conductive layer exposed at its surface to a grazing angle X-ray diffraction (GIXRD) characterization, and extracting crystal properties of the thermal conducive layer from a resulted diffractogram;
using the correlations established by the preliminary experiments to find thermal properties corresponding to the extracted crystal properties of the thermal conductive layer; and
further processing the intermediate structure to complete formation of the semiconductor package.

13. The method for manufacturing the semiconductor package according to claim 12, wherein the substrate is a semiconductor wafer, and the method further comprises forming active devices on the substrate and forming metallization layers on the active devices before formation of the thermal conductive layer.

14. The method for manufacturing the semiconductor package according to claim 12, wherein further processing the intermediate structure comprises forming conductive features in the thermal conductive layer.

15. The method for manufacturing the semiconductor package according to claim 12, wherein further processing the intermediate structure comprises:
singulating the intermediate structure to obtain a first semiconductor die; and
bonding the first semiconductor die with a second semiconductor die.

16. The method for manufacturing the semiconductor package according to claim 15, wherein the thermal conductive layer in the first semiconductor die is bonded with another thermal conductive layer formed along a bonding surface of the second semiconductor die.

17. The method for manufacturing the semiconductor package according to claim 15, wherein further processing the intermediate structure also comprises forming a bonding layer on the thermal conductive layer before singulating the intermediate structure, and the first semiconductor die is bonded to the second semiconductor die by the bonding layer.

18. The method for manufacturing the semiconductor package according to claim 15, wherein further processing the intermediate structure comprises: attaching the intermediate structure to a heat dissipation module by the thermal conductive layer.

19. The method for manufacturing the semiconductor package according to claim 12, wherein the substrate is a package structure comprising a semiconductor die and a surrounding encapsulant.

20. A method for manufacturing a semiconductor package with a thermal conductive layer, comprising:
conducting preliminary experiments, to establish correlations between crystal properties and thermal properties of thin film samples formed of a crystalline material identical with a crystalline material for forming the thermal conductive layer;
depositing the thermal conductive layer over a substrate;
subjecting an intermediate structure with the thermal conductive layer exposed at its surface to a grazing angle X-ray diffraction (GIXRD) characterization, and extracting crystal properties of the thermal conducive layer from a resulted diffractogram;
using the correlations established by the preliminary experiments to find thermal properties corresponding to the extracted crystal properties of the thermal conductive layer;
determining if at least one of the thermal properties of the thermal conductive layer is greater than a predetermined expectation level;
when the at least one of the thermal properties of the thermal conductive layer is greater than the predetermined expectation level, then further processing the intermediate structure to complete formation of the semiconductor package; and
if the at least one of the thermal properties of the thermal conductive layer is lower than the predetermined expectation level, then performing a next cycle from depositing another thermal conductive layer on another substrate by using adjusted deposition parameters.
